(19) United States
(12) Patent Application Publication
(10) Pub. No.: US 2008/0131602 A1
(43) Pub. Date: Jun. 5, 2008

(54) METHOD OF PREPARING CATALYST FOR CATALYZING GROWTH OF SINGLE-WALL CARBON NANOTUBES

(75) Inventors: Wei-Hsiang WANG, Hsinchu City (TW); Cheng-Tzu KUO, Hsinchu City (TW); Tsai-Hau HONG, Hsinchu City (TW)

Correspondence Address: LOWE HAUPTMAN HAM & BERNER, LLP, 1700 DIAGONAL ROAD, SUITE 300, ALEXANDRIA, VA, 22314, US

(73) Assignee: RITEK CORPORATION, Hsinchu Industrial Park (TW)

(21) Appl. No.: 11/749,493

(22) Filed: May 16, 2007

(30) Foreign Application Priority Data
Jun. 1, 2006 (TW) 95119470

(51) Int. Cl. B05D 3/04; C23C 16/40; C23C 16/00; C23C 14/00

(52) U.S. Cl. 427/255.31; 427/337; 204/192.11; 204/192.12

(57) ABSTRACT

Chemical vapor deposition (CVD) is used to synthesize single-wall carbon nanotubes by a catalytic reaction, and a method of preparing the catalyst is also provided. A transition metal catalyzing growth of carbon nanotubes, an oxide of a precursor metal preventing agglomeration of catalyst particles, and a precious metal are essentially consisted in the catalyst. The catalyst particles can be further dispersed by quasi-explosive effect occurred when the oxidized precious metal is reduced.

### CROSS-REFERENCE TO RELATED APPLICATION

The application claims priority to Taiwan Application Serial Number 95119470, filed Jun. 1, 2006, which is herein incorporated by reference.

### BACKGROUND

1. Field of Invention

The present invention relates to synthesizing carbon nanotubes. More particularly, the present invention relates to synthesizing single-wall carbon nanotubes by a new catalyst.

2. Description of Related Art

Since the discovery of carbon nanotubes (CNT), lots of attentions have been concentrated on CNT because of its excellent mechanical properties and large specific surface. Hence, CNT can be applied on hydrogen storage, catalyst support, electrochemical supercapacitor, anode of lithium cell, and cathode electron emitter of field emission display.

Due to the unique physical properties of single-wall carbon nanotubes (SWNT), such as excellent heat transfer property, modulable electrical conductivity, very large aspect ratio, and very large specific surface, SWNT has become research focus of industry and academia in recent years. Conventionally, SWNT was synthesized by arc discharging and laser ablation. The purity of SWNT synthesized by the two methods mentioned above was high. However, the synthesizing temperatures required by the two methods were quite high (above 1200° C.), and the yield of SWNT was low. Therefore, high production cost and low practicability can be expected, especially when being applied on integrated circuits production.

In recent years, synthesis of SWNT by chemical vapor deposition (CVD) has been widely studied, since CVD has advantages of lower synthesizing temperature and higher yield. CVD has good performance on synthesizing multi-wall carbon nanotubes (MWNT) but lack of control of yield, purity, and temperature on synthesizing SWNT. Hence, the accompanied high SWNT production cost problem prevents SWNT from wide industrial application. The disclosed CVD method of synthesizing SWNT has very low yield rate, and the manufactured SWNT were mixed with MWNT. Furthermore, since the CNT synthesizing temperature (about 900-1000° C.) is lower than that of arc discharging, the quality of synthesized CNT was greatly reduced because of lower graphitization. Moreover, the synthesizing temperature (900° C.) is not compatible to the existing integrated circuit manufacturing processes. Although a buffer layer was proposed to effectively lower the synthesizing temperature to 600-700 oC, the purity and the yield of the obtained SWNT was even lower.

### SUMMARY

A new catalyst for catalyzing growth of single-wall carbon nanotubes is provided. The new catalyst essentially consists of a transition metal for catalyzing growth of carbon nanotubes, an oxide of a precursor metal for preventing agglomeration of catalyst particles, and a precious metal for dispersing the catalyst particles by a quasi-explosive effect occurred when the precious metal in its oxidized form is reduced.

According to an embodiment of this invention, the weight ratio of the transition metal: the oxide of the precursor metal: the precious metal is about 20-90: 5-30: 5-60.

According to another embodiment of this invention, the transition metal comprises Fe, Co or Ni.

According to another embodiment of this invention, the oxide of the precursor metal comprises chromium oxide, tantalum oxide, vanadium oxide, or titanium oxide.

According to another embodiment of this invention, the precious metal comprises Pt, Ag, Au, or Pd.

A method of preparing a new catalyst for catalyzing growth of single-wall carbon nanotubes is provided. A metal oxide film is deposited on a substrate, and the metal oxide film essentially consists of an oxide of a transition metal, an oxide of a precursor metal, and an oxide of a precious metal. The metal oxide film is then partially reduced by a reducing gas to obtain the new catalyst film. After reduction, oxides of the transition metal and the precursor metal are reduced to elemental metal state, but the oxide of the precursor metal are only partially reduced to prevent agglomeration of catalyst particles.

According to an embodiment of this invention, the oxygen content in the metal oxide film is about 20-70% by mole.

According to another embodiment of this invention, the transition metal comprises Fe, Co or Ni for catalyzing carbon nanotubes growth.

According to another embodiment of this invention, the precursor metal comprises Cr, Ta, V or Ti. The oxide of the precursor metal is capable of preventing agglomeration of catalyst particles.

According to another embodiment of this invention, the precious metal comprises Pt, Ag, Au, or Pd. The catalyst particles can be dispersed by a quasi-explosive effect occurred when the oxide of the precious metal is reduced.

A method of synthesizing single-wall carbon nanotubes is provided. The single-wall carbon nanotubes are synthesized by chemical vapor deposition catalyzed by a new catalyst. The new catalyst essentially consists of a transition metal for catalyzing growth of carbon nanotubes, an oxide of a precursor metal for preventing agglomeration of catalyst particles, and a precious metal for dispersing the catalyst particles by a quasi-explosive effect occurred when the precious metal in its oxidized form is reduced. The new catalyst is placed in a reaction chamber of chemical vapor deposition, and a carbon source gas is introduced to the reaction chamber to grow the single-wall carbon nanotubes.

According to an embodiment of this invention, the weight ratio of the transition metal: the oxide of the precursor metal: the precious metal is about 20-90: 5-30: 5-60.

According to another embodiment of this invention, the transition metal comprises Fe, Co or Ni.

According to another embodiment of this invention, the oxide of the precursor metal comprises chromium oxide, tantalum oxide, vanadium oxide, or titanium oxide.

According to another embodiment of this invention, the precious metal comprises Pt, Ag, Au, or Pd.

According to another embodiment of this invention, the carbon source gas comprises methane, ethene, or ethyne.

It is to be understood that both the foregoing general description and the following detailed description are made by use of examples and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is an X-ray photoelectron spectrum (XPS) of the Co₇CrPtO₁₁ film before and after H₂ reduction;

FIG. 2 is a photograph, obtained from high-resolution transmission electron microscope (HRTEM), showing the Co—Cr₂O₃—Pt film;

FIG. 3 is a photograph, obtained from field emission scanning electronic microscopy (FESEM), showing plenty of single-wall carbon nanotubes obtained in a reaction catalyzed by the Co—Cr₂O₃—Pt film;

FIG. 4 is a Raman spectrum showing the radial breathing mode (RBM) of carbon nanotubes vibration.

FIG. 5 is a Raman spectrum showing the tangential vibration mode of carbon nanotubes vibration.

### DETAILED DESCRIPTION

There are two issues to be concerned when synthesizing SWNT. One is the catalytic activity of the catalyst used. The other is how to pulverize and disperse catalyst particles. The available catalysts for synthesizing CNT are transition metals including Fe, Co, and Ni. These transition metals have high carbon melting temperature (higher than 700° C.) in their bulky metal states, but the problem can be overcome by adjusting the metal alloy composition of the catalyst and using the catalyst in a thin film state. There are more difficulties in pulverizing and dispersing catalyst particles. For SWNT, the diameter of the SWNT (about 1-3 μm) is determined by the particle size of the catalyst. If the particle size of the catalyst is too large, the catalyst cannot catalyze SWNT growth. Hence, how to pulverize catalyst particles and prevent agglomeration of catalyst particles are two important issues on synthesizing SWNT.

### Catalyst Used to Catalyze Synthesis of Single-Wall Carbon Nanotubes

A new catalyst provided here is a catalyst for catalyzing synthesis of single-wall carbon nanotubes. The catalyst essentially consists of a transition metal for catalyzing growth of carbon nanotubes, an oxide of a precursor metal for preventing agglomeration of catalyst particles, and a precious metal for dispersing the catalyst particles by a quasi-explosive effect occurred when the precious metal in its oxidized form is reduced. The weight ratio of the transition metal: the oxide of the precursor metal: the precious metal is about 20-90: 5-30: 5-60.

The transition metal for catalyzing growth of carbon nanotubes can be those commonly disclosed in literatures, such as Fe, Co or Ni. For example, Lee et al. used Fe to catalyze SWNT growth (Applied Physics Letters, 2000, vol. 77, p. 3397). Juang et al. used Ni to catalyze SWNT growth (Diamond and Related Materials, 2004, vol. 13, p. 1203; Diamond and Related Materials, 2004, vol. 13, p. 2140). Rao et al. used Ni/Co to catalyze SWNT growth (Science, 1997, vol. 275, p. 187).

The oxide of the precursor metal can be, for example, chromium oxide, tantalum oxide, vanadium oxide, or titanium oxide. Namely, the precursor metal can be, for example, Cr, Ta, V, or Ti. The oxide of the precursor metal can prevent agglomeration of catalyst particles from forming large catalyst particles during reducing a metal oxide film, which is the precursor of the catalyst film, and catalyzing SWNT growth under a high temperature. In other words, the oxide of the precursor metal can stabilize the catalyst nanoparticles, and the catalyst nanoparticles will not agglomerate to large catalyst particles. As described above, the particle size of the catalyst is critical for SWNT growth. If the particle size of the catalyst is too large, MWNT, instead of SWNT, will be grown.

Take chromium oxide as an example, in the research of Shaijumon et al. (Applied Surface Science, 2005, vol. 242, p. 192), nickel cations and chromium cations were supported in a layered clay, and counter ions are carbonate anions. After calcination at 500° C., nickel and chromium cations were respectively transformed to NiO and Cr₂O₃ in a particle size of about 8 nm. NiO was then reduced by hydrogen to form Ni fine particles dispersed in Cr₂O₃, and a catalyst having high catalytic activity for catalyzing SWNT growth was thus obtained.

The precious metal described above can be, for example, Pt, Ag, Au, or Pd. When oxides of these precious metals are reduced, a quasi-explosive effect is occurred to disperse catalyst particles into nanoparticels. For example, in the research of Kikukawa et al., a PtO₂ thin film can release oxygen to form bubbles in the PtO₂ thin film after being irradiated by a laser beam. Fine particles of Pt in a size of about 20 nm were dispersed in the bubbles. Hence, the capacity of a compact disk (CD) can be increased to about 200 GB (Applied Physics Letter, 2002, vol. 81, p. 4697; Applied Physics Letter, 2003, vol. 83, p. 1701).

### Synthesis of Catalyst Precursor Capable of Catalyzing Swnt Growth

A metal oxide film, i.e. the precursor of the catalyst film, is deposited on a substrate. The metal oxide film essentially consists of an oxide of the transition metal, an oxide of the precursor metal, and an oxide of the precious metal. The oxygen content in the metal oxide film is about 20-70% by mole. The transition metal, the precursor metal and the precious metal have been described as above and hence omitted here.

In one embodiment, the thickness of the metal oxide film is about 0.5-15 nm. In another embodiment, the thickness of the metal oxide film is about 1-5 nm. The thickness of the metal oxide film is determined by the desired diameter of the synthesized SWNT. If the desired diameter of SWNT is large, the thickness of the metal oxide film needs to be large.

The metal oxide film can be deposited by, for example, physical vapor deposition or chemical vapor deposition. The physical vapor deposition can be, for example, magnetron enhanced sputtering, ion beam sputtering, or reactive sputtering.

The substrate has to be capable of enduring a high temperature of about 500-1100° C. The substrate can be, for example, a quartz substrate, a silicon substrate, or a metal substrate having high melting point.

### Treatment of the Catalyst Precursor to Form a Catalyst Film

The metal oxide film are then reduced under an ambient atmosphere of a reducing gas or a mixture of a reducing gas and an inert gas under a temperature high enough to partially reduce the metal oxide film to obtain the catalyst film. The reducing gas can be, for example, H₂, NH₃ or a combination thereof. The inert gas can be, for example, Ar or N₂.

After reduction, oxides of the transition metal and the precursor metal are reduced to their elemental metal states, but the oxide of the precursor metal is only partially reduced to prevent agglomeration of catalyst particles.

### Synthesis of Single-Wall Carbon Nanotubes (SWNT)

The catalyst film on the substrate is placed in a reaction chamber full of the reducing gas or the mixture of the reducing gas and the inert gas. The temperature of the reaction chamber is then raised to a temperature capable of catalyzing SWNT growth. A carbon source gas, such as CH₄, C₂H₄, or C₂H₂, is introduced to the reaction chamber to start growing SWNT. After a period of time, SWNT can be detached from the substrate, and the catalyst film on the substrate can be reactivated. The reactivation condition of the catalyst film is under a reducing atmosphere at a temperature above 550° C. for a period of time.

### Example of Synthesizing SWNT

Various metal oxide films were deposited by reactive sputtering using various metal targets under 10 sccm of H₂ and 20 sccm of O₂. The thickness of the deposited metal oxide film was about 1 nm or about 3 nm. The metal targets used above were Co—Cr—Pt (58:30:12 in weight ratio), Co—Pt (70:30 in weight ratio), and Co—Cr (52:48 in weight ratio), respectively. The composition of the metal oxide film deposited by using Co—Cr—Pt target was Co₇CrPtO₁₁.

The metal oxide films were then treated to form catalyst films. The three kinds of metal oxide films were placed in a reaction chamber of microwave plasma vapor deposition (MPCVD) under 100 sccm of H₂ and 600° C. to reduce the metal oxide films for about 10 minutes.

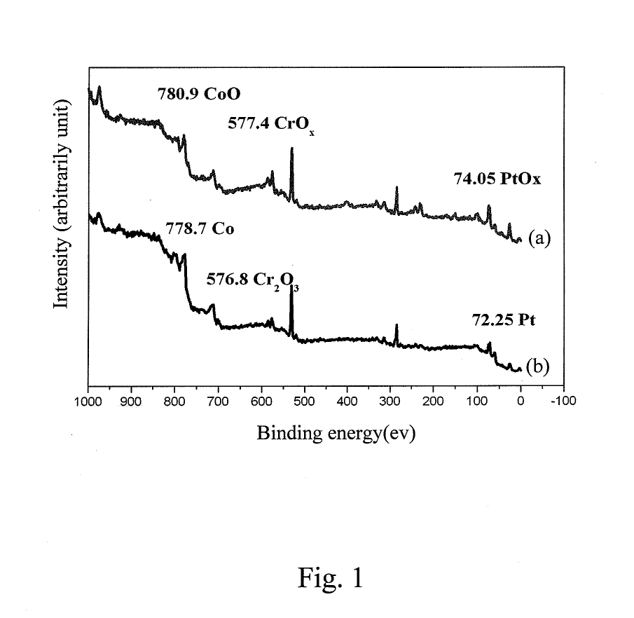

FIG. 1 is an X-ray photoelectron spectrum (XPS) of the Co₇CrPtO₁₁ film before and after H₂ reduction. In FIG. 1, spectrum (a) is XPS of Co₇CrPtO₁₁ film before H₂ reduction, and signals of cobalt oxide (780.9 eV), chromium oxide (577.4 eV), and platinum oxide (74.05 eV) can be clearly observed. Spectrum (b) is XPS of Co₇CrPtO₁₁ film after H₂ reduction, and signals of cobalt (778.7 eV), Cr₂O₃ (576.8 eV), and platinum (72.25 eV) were detected. It is shown that cobalt oxide and platinum oxide were completely reduced to cobalt metal and platinum metal, and chromium oxide was partially reduced to Cr₂O₃. Therefore, the catalyst film is a Co—Cr₂O₃—Pt film. Co is used to catalyze growth of carbon nanotubes. Cr₂O₃ is used to prevent agglomeration of catalyst particles. Pt is a precious metal.

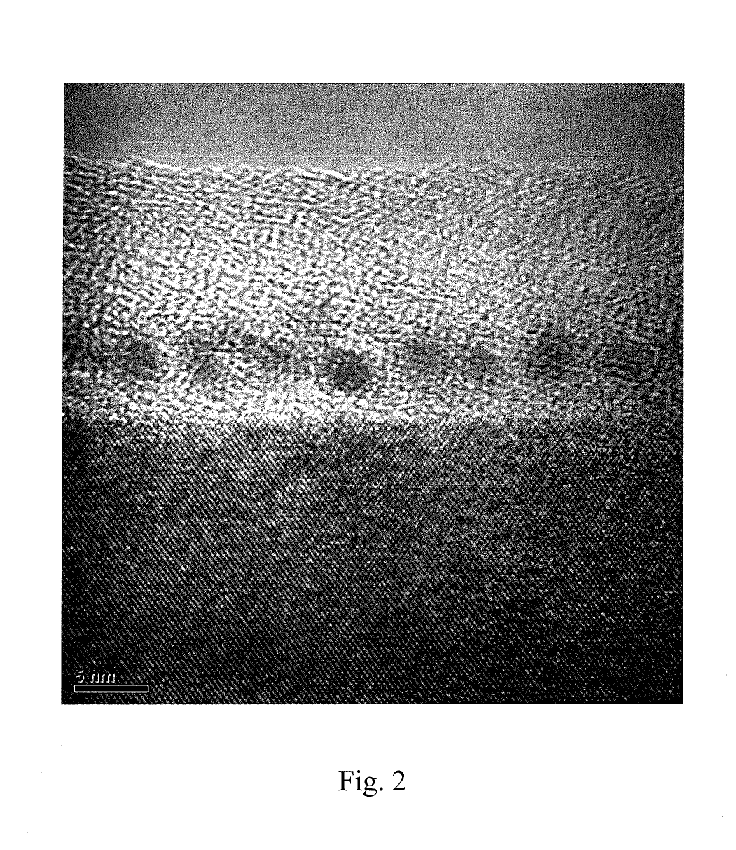

FIG. 2 is a photograph, obtained from high-resolution transmission electron microscope (HRTEM), showing the Co—Cr₂O₃—Pt film obtained by reducing the Co₇CrPtO₁₁ film. The sample of Co—Cr₂O₃—Pt film was polished first and then examined by HRTEM. In FIG. 2, the size of catalyst particle was about 3-4 nm, which shows the design of the alloy describe above is proper for keeping catalyst particle size suitable for catalyzing SWNT growth.

Next, carbon nanotubes were grown in the reaction chamber of MPCVD system as described above. 5 sccm of CH₄ and 50 sccm of H₂ were introduced into the reaction chamber, and the temperature of the reaction chamber was raised to 64° C. Methane can be adsorbed byCo so carbon melting reaction and carbon nanotubes growth reaction can be catalyzed. After 10 minutes, temperature was cooled down to about room temperature and then product can be taken out of the reaction chamber. Only Co—Cr₂O₃—Pt film can catalyze SWNT growth, the other two types of catalyst films did not catalyze SWNT growth, as shown in Table 1.

TABLE 1

| Metal composition | | |
|---|---|---|
| of catalyst film | thickness (nm) | product |
| Co—Cr | 1 | Some MWNT |
| | 3 | Some MWNT |
| Co—Pt | 1 | No CNT |
| | 3 | No CNT |
| Co—Cr—Pt | 1 | SWNT |
| | 3 | SWNT |

MWNT: multi-wall carbon nanotubes; SWNT: single-wall carbon nanotubes; CNT: carbon nanotubes.

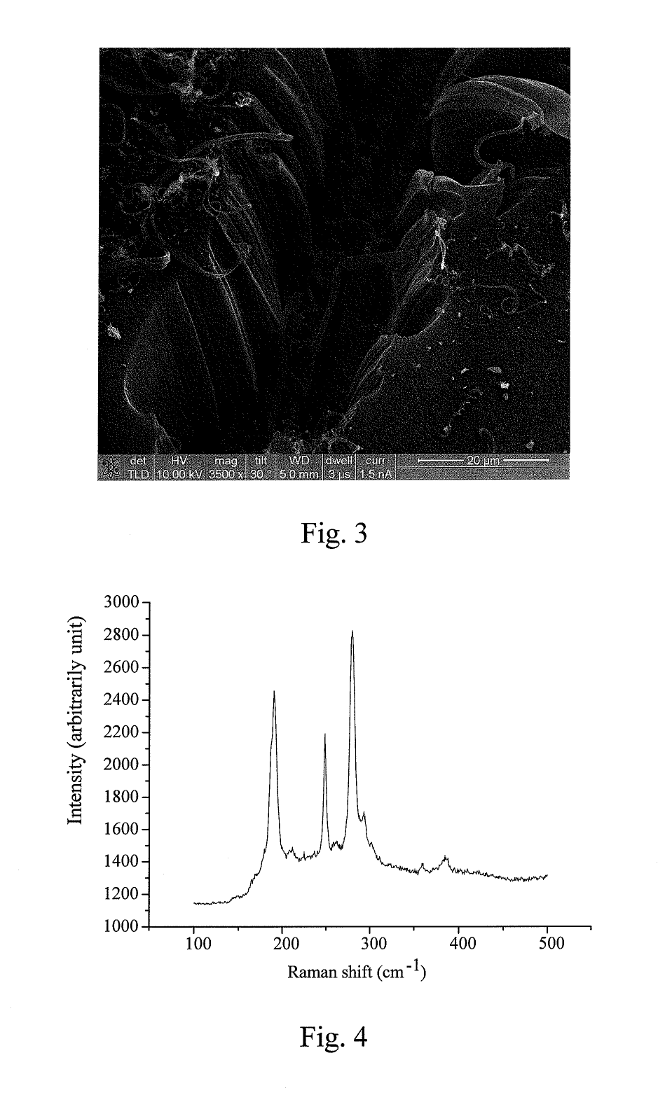

The SWNT obtained in the reaction catalyzed by Co—Cr₂O₃—Pt film was shown in FIG. 3. A lot of SWNT can be observed in FIG. 3 obtained by field emission scanning electronic microscopy (FESEM).

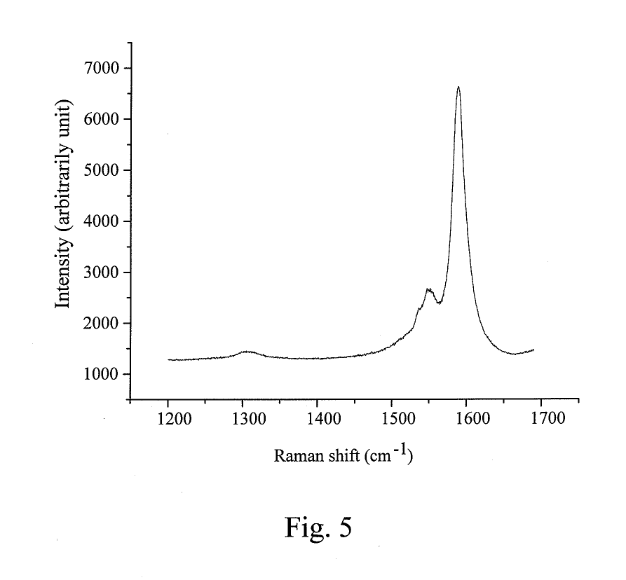

Raman spectra of SWNT obtained by Co—Cr₂O₃—Pt catalyst were shown in FIGS. 4 and 5. FIG. 4 shows the radial berthing mode (RBM) of carbon nanotubes vibration. The vibration peaks, from left to right, were 190, 240, 290 cm⁻¹. The first and the second peaks are RBM vibration peaks (Physical Review B, 2002, vol. 65, p. 155412). The third peak is the vibration peak of silicon substrate. Since each RBM peak represents SWNT with a specific diameter, and only two RBM peaks appear in FIG. 4, it indicates the diameter distribution range of the obtained SWNT is quite concentrated.

Raman spectrum in FIG. 5 shows the tangential vibration mode of carbon nanotubes vibration, namely the G band signal (Physical Review B, 2002, vol. 65, p. 155412). The peak of about 1350 cm⁻¹ represents the vibration signal of sp³ hybridization carbon, i.e. diamond like carbon. The peak of about 1580 cm⁻¹ represents the vibration signal of sp² hybridization carbon, i.e. graphite like carbon. Generally speaking, for SWNT, the vibration peak intensity of diamond like carbon (Id) is smaller than the vibration peak intensity of graphite like carbon (Ig). For MWNT, the vibration peak intensity of diamond like carbon (Id) is larger than the vibration peak intensity of graphite like carbon (Ig). Therefore, the ratio of Ig/Id is larger, the purity of SWNT is higher. Table 2 lists the Ig/Id for various SWNT from various sources. Table 2 shows the purity of SWNT provided by the example of this invention is much higher than the SWNT from commercial sources.

TABLE 2

| Source of SWNT | Synthesis method | Ig/Id |
|---|---|---|
| Commercial product of Times nano | Chemical vapor deposition | 9.5 |
| ASA-100F of ILJIN | Arc dischargig | 18.8 |
| SP 2582 of Thomas SWAN | Arc dischargig | 36.4 |
| Example of this invention | Chemical vapor deposition | 43.0 |

It can be known from the embodiments of this invention that new catalyst for catalyzing SWNT growth can be obtained by depositing the metal oxide film containing three types of metal oxides and then reducing the metal oxide film, as described above. This new catalyst can raise the SWNT purity and decrease the diameter distribution range of SWNT.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of preparing a catalyst for catalyzing growth of single-wall carbon nanotubes, the method comprising:
depositing a metal oxide film on a substrate, the metal oxide film consisting essentially of:
an oxide of a transition metal, which can catalyze growth of carbon nanotubes;
an oxide of a precursor metal, the oxide of the precursor metal is capable of preventing agglomeration of catalyst particles; and
an oxide of a precious metal, wherein the catalyst particles can be dispersed by a quasi-explosive effect occurred when the oxide of the precious metal is reduced; and
introducing a reducing gas to the metal oxide film to reduce the metal oxide film, so that a catalyst film can be formed and the catalyst film consists essentially of the transition metal, the precious metal and a partially reduced oxide of the precursor metal.

2. The method of claim 1, wherein the metal oxide film contains about 20 to about 70% by mole of oxygen.

3. The method of claim 1, wherein the transition metal comprises Fe, Co or Ni.

4. The method of claim 1, wherein the precursor metal comprises Cr, Ta, V, or Ti.

5. The method of claim 1, wherein the precursor metal comprises Cr.

6. The method of claim 1, wherein the precious metal comprises Pt, Ag, Au, or Pd.

7. The method of claim 1, wherein the precious metal comprises Pt.

8. The method of claim 1, wherein a composition of the metal oxide film is Co₇CrPtO₁₁.

9. The method of claim 1, wherein the reducing gas comprises H₂, NH₃ or a combination thereof.

10. The method of claim 1, wherein the metal oxide film is deposited by chemical vapor deposition or physical vapor deposition.

11. The method of claim 10, wherein the physical vapor deposition comprises magnetron enhanced sputtering, ion beam sputtering, or reactive sputtering.
